(19) United States
(12) Patent Application Publication
(10) Pub. No.: US 2026/0235540 A1
(43) Pub. Date: Aug. 13, 2026

(54) INDUCTIVE ARRAY, OSCILLATOR ASSEMBLY, DEVICE, AND METHOD FOR GENERATING AND/OR DETECTING A MAGNETIZATION OF A SAMPLE

(71) Applicant: Universitaet Stuttgart, Koerperschaft des Oeffentlichen Rechts, Stuttgart (DE)

(72) Inventors: Anh Chu, Stuttgart (DE); Jens Anders, Stuttgart (DE)

(21) Appl. No.: 19/156,581

(22) PCT Filed: Jan. 9, 2024
(86) PCT No.: PCT/EP2024/050358

§ 371 Date: Aug. 14, 2025

(30) Foreign Application Priority Data
Feb. 17, 2023 (DE) 10 2023 103 994.6

(51) Int. Cl. G01N 24/08; G01N 24/10

(52) U.S. Cl. CPC G01N 24/08; G01N 24/10

(57) ABSTRACT

The invention relates to an inductive array, in particular for use in an oscillator assembly for generating and/or detecting a magnetization of a sample, having a plurality of interconnected inductive segments, wherein each of the inductive segments has an inductive element and a connection circuit, which is electrically connected to the inductive element, for electrically connecting to an adjacent inductive segment.

### CROSS-REFERENCE TO RELATED APPLICATIONS

The present patent application claims the priority of German patent application No. 10 2023 103 994.6 of Feb. 17, 2023, the disclosure content of which is fully integrated into the present description by this reference.

### FIELD AND BACKGROUND OF THE INVENTION

The invention relates to an inductive assembly, in particular for use in an oscillator arrangement for generating and/or detecting a magnetization of a sample.

The invention furthermore relates to an oscillator arrangement, in particular for use in an apparatus for generating and/or detecting a magnetization of a sample.

The invention moreover also relates to an apparatus and a method for generating and/or detecting a magnetization of a sample, in particular for electron spin resonance spectroscopy or nuclear magnetic resonance spectroscopy.

The invention relates in particular to generating and/or detecting a magnetic resonance of a sample, such as used, for example, in electron spin resonance spectroscopy and nuclear magnetic resonance spectroscopy, which are used, inter alia, in experimental physics, chemistry, medical technology or the geosciences.

In Electron Spin Resonance Spectroscopy (abbreviated as ESR; sometimes also referred to as EPR (Electron Paramagnetic Resonance)) and Nuclear Magnetic Resonance Spectroscopy (abbreviated as NMR), samples in a statically homogeneous, statically inhomogeneous or dynamic (pulsed inhomogeneous) magnetic field, commonly referred to as B₀, are exposed to additional high-frequency alternating electromagnetic fields (in ESR, most commonly in the microwave range between 1 and 263 GHz), commonly referred to as B₁.

By coupling alternating fields (B₁) of suitable frequency and polarization, transitions between the energy levels of discrete spin states of the nucleus and/or electron configuration of a sample are induced, which in turn lead to absorption processes in the alternating field, which can be detected. Various substance-analytical information of the sample can be determined from the detected absorption processes. In this case, the B₁ field is usually oriented perpendicular to B₀.

Samples open to characterization by ESR or NMR experiments are accordingly all linearly magnetizable samples, i.e. paramagnetic samples with unpaired electrons (ESR) or diamagnetic samples with nuclei with “net nuclear spin” due to an odd number of nucleons (NMR). The samples can be liquid, solid or gaseous. Hereinbelow, the term “sample” usually always refers to a magnetizable sample, as introduced above.

For further technological background, reference should be made to DE 10 2016 102 025 A1 or WO 2017/088852 A1, the respective disclosure content of which is fully integrated into the present patent application by this reference.

Electron spin resonance spectroscopy is a powerful method which uses the spin of an unpaired electron as a nanoscopic probe inside a molecule in order to obtain information about the chemical structure and composition via small changes in the resonance frequency.

Electron spin resonance spectroscopy is used when examining and monitoring a broad spectrum of materials, from defects in semiconductors to free radicals in blood to metal catalysts in the production of hydrogen as fuel. The measurements are usually performed in moderate static magnetic fields of around 0.3 T, this corresponding to ESR frequencies of around 9 GHz. This combination of magnetic flux density and ESR frequency is widely used since it is technically usually readily possible to generate 0.3 T magnetic fields with sufficient homogeneity and the required 9 GHz frequency signal.

However, access to higher frequencies and magnetic fields would be desirable owing to the possibility of a higher spin polarization (with correspondingly larger signal amplitude), a higher spectral resolution (e.g. for determining the electronic and geometric structures of active centers in enzymes), and the access to higher-energy transitions (such as, e.g., occurring in metal complexes or materials which are of interest in antiferromagnetic spintronics). High-frequency ESR (HFEPR or HFESR) with operating frequencies above 90 GHz are therefore desirable.

Another important driving force for HFESR is dynamic nuclear polarization (DNP), a method which can be used to improve the relatively low sensitivity of nuclear magnetic resonance spectroscopy by transferring the higher electron polarization per se to the nuclear spins. Currently, known on the market is mainly a commercial HFESR-based DNP spectrometer with an ESR operating frequency of 263 GHz (9.4 T), this corresponding to a proton NMR frequency of 400 MHz. The known spectrometer uses a gyrotron as a source for the millimeter wave magnetic field (B₁ field) and is extraordinarily expensive to purchase.

Present HFESR spectrometers use one of four methods to generate B₁ fields for the HFESR/DNP: Vacuum tubes (gyrotrons and backward-wave oscillators), active frequency multiplier chains, synchrotron radiation and, lately, THz photomixers.

However, all these methods have significant drawbacks in terms of their complexity and cost. The first three methods have to use large, complex quasi-optical arrangements (size>1 m²) to efficiently manipulate the millimeter wave, and moreover use cryogenically cooled radiation detectors (bolometers) for sufficiently sensitive detection. THz photomixers require only a few THz lenses but for this purpose require complex fiber optic equipment to achieve sufficient spectral resolution and are less sensitive than the other three methods.

In order to overcome the limitations of conventional ESR designs, a number of oscillator-based CMOS-integrated ESR detectors (“EPR/ESR-on-a-chip”) for different fundamental frequencies of up to 146 GHz have been presented in recent years. For example, voltage-controlled oscillators (VCOs) were proposed as electron spin resonance (ESR) sensors in the publication by Handwerker, J. et al. “A 14 GHz battery-operated point-of-care ESR spectrometer based on a 0.13 μm CMOS ASIC”, IEEE International Solid-State Circuits Conference (ISSCC), pp. 476-477 in 2016. This technique enables a frequency sweep of the VCO frequency with almost constant sensitivity over all the resonance frequencies of the sample. Since then, this technique has gained increasing attention in the research community since it can lead to extreme miniaturization of the entire ESR spectrometer at very low cost.

In the meantime, improvements to this basic concept have also already been proposed in order to extend the oscillation frequency to the millimeter wave range for better spin sensitivity. Furthermore, approaches are known to simplify the modulation and demodulation electronics (cf. Benedikt Schlecker et al., “Towards Low-Cost, High-Sensitivity Point-of-Care Diagnostics Using VCO-Based ESR-on-a-Chip Detectors”, IEEE Sensors Journal, vol. 19, no. 20, pp. 8995-9003, 2019.), and to excite and detect the transient response of electron spin assemblies (Silvio Künstner et al., “Rapid Scan Electron Paramagnetic Resonance using an EPR-on-a-chip Sensor”, Magnetic Resonance, May 2021).

In the publication by Matheoud, A. V. et al., “Single-chip electron spin resonance detectors operating at 50 GHz, 92 GHz, and 146 GHz”, Journal of Magnetic Resonance, 278, 113-121, 2017, a single HFESR oscillator operated at 90 GHz was used, for example, for ESR measurement at 360 GHz using its fourth harmonic—but with comparatively lower excitation power and sensitivity. Due to the small coil diameter of only 45 μm for the 146 GHz oscillator, caused by the wavelength of the fundamental frequency, and the associated very small active volume, the method furthermore cannot be used effectively for ESR and DNP experiments at very high operating frequencies.

Although VCOs have demonstrated their great potential as extremely robust and user-friendly ESR sensors for solid samples with limited mass, their use for the spectroscopic measurement of liquid samples is still limited due to the relatively low concentration sensitivity (i.e. the minimal detectable spin density in a liquid sample which fills the entire volume) with respect to the relatively small measurement volumes of the planar chip-integrated (“on-chip”) detectors.

One approach for achieving a larger detectable volume would be to use chip-integrated coils with a larger diameter. However, compromises are required when choosing the coil size. First and foremost, this is because the maximum coil diameter is limited by the wavelength associated with the VCO operating frequency. In order to avoid radiation losses and large electrical fields within the sample, the total length of the coil path should not exceed a certain fraction a of the wavelength, wherein a is typically between 5 and 10. Secondly, the large inductances associated with large-diameter coils prevent large VCO tuning ranges and result in comparatively high phase noise.

One approach for increasing the detectable volume of VCO-based ESR detectors was presented by Anh Chu et al. in the publication “An 8-Channel 13GHz ESR-on-a-chip injection-locked VCO-array achieving 200 μm-concentration sensitivity”, IEEE International Solid-State Circuits Conference (ISSCC), pp. 354-355, in 2018. In this case, injection locking between a large number of planar VCOs was used to synchronize all the participating VCOs to a single, common frequency and phase. The use of “injection-locked” VCO arrays can advantageously contribute to increasing the laterally detectable volume and to simultaneously reducing the phase noise.

However, this technique does not allow the enlargement of a single array element and therefore also does not allow the enlargement of the detectable volume perpendicular to the planar array. In addition, due to the injection locking, the signals of the single VCOs are not added, such that the improvement in the concentration sensitivity occurs only due to the improved phase noise. There is therefore still a need for a method which increases the active volume both laterally and perpendicular to the coil surface. When increasing the active volume perpendicular to the coil surface, it should be noted that the sensitivity along this spatial direction decreases very quickly according to the previously known prior art, depending on the coil diameter.

### SUMMARY OF THE INVENTION

In view of the known prior art, the object of the present invention is, inter alia, to provide an inductive assembly which can be used to achieve a large active volume for excitation and detection and a high concentration sensitivity, preferably at low energy consumption.

The present invention is also based, inter alia, on the object of providing an oscillator arrangement which can be used to achieve a large active volume for excitation and detection and a high concentration sensitivity, preferably at low energy consumption.

Moreover, it is, inter alia, an object of the invention to provide an apparatus and a method for generating and/or detecting a magnetization of a sample, which can be used to achieve a large active volume for excitation and detection and a high concentration sensitivity, at preferably low energy consumption.

For the inductive assembly, the oscillator arrangement, and apparatus, the objects of the invention are achieved by the features disclosed herein.

The invention relates to an inductive assembly, in particular (but not exclusively) for use in an oscillator arrangement for generating and/or detecting a magnetization of a sample.

The inductive assembly has a plurality of interconnected inductive segments, wherein each of the inductive segments has an inductive element and a connection circuit, which is electrically connected to the inductive element, for electrically connecting to an adjacent inductive segment.

Solid, gaseous and/or liquid samples can be used as samples. Liquid samples can be placed, e.g., in glass capillaries on planar designs (e.g. in CMOS technology). At lower frequencies from B₁ up to the so-called X-band (approx. 10 GHz), the coils of the LC oscillators can also be realized as volume coils into which the capillaries comprising liquid samples can be introduced, or else be combined with (micro-)fluidic systems for transporting samples into the detector. Alternatively, the apparatus can also be immersed or introduced into the liquid, gas or solid to be measured, or be combined therewith in another way, such as, e.g., by spraying. Phase transitions and changes (transitions) in aggregate states are thus detectable. Alternatively, a hole can furthermore also be drilled in the planar coils, e.g., by means of a laser, in order to introduce a liquid sample.

In an advantageous manner, the invention can greatly increase the size of the “tank inductance”, e.g. beyond the limit of λ/α (in this case a can be any number between 1 and 50, e.g. 5 to 10). The enlarged composite coil (referred to above and below also as an “inductive assembly”) can finally be divided into shorter sub-sections (referred to above and below also as “inductive elements”). Each sub-segment or inductive element can be controlled by suitable electronics (referred to above and below also as a “connection circuit”), e.g. in the form of individual VCO cores.

By embedding phase coupling circuits between the electronic control blocks, the phases thereof can be synchronized such that a circulating current flows inside the large composite coil or the inductive assembly as a whole, which replicates the response of a hypothetical large-diameter coil. At the same time, radiation losses and parasitic electric fields remain low.

When using the proposed splitting technique (referred to below also as the “split coil” technique), each inductive segment has a greatly reduced inductance, allowing for low phase noise and wide tuning ranges. This applies in particular when the individual electronic driver blocks or connection circuits between the inductive elements are designed as VCO cores or have VCO cores, and the entire system, that is to say the entire inductive assembly, thus likewise acts as a VCO.

It should be noted that the possibility of dividing a coil into a plurality of segments with VCO cores arranged therebetween was already proposed by R. Aparicio and A. Hajimiri in the publication “Circular-geometry oscillators” ISSCC, p. 378-533 in 2004 in order to increase the Q factor of the coil. By contrast, the segmented coil technique in the present invention is used to provide enlarged inductors or inductive assemblies as sensors for HFESR and B₁ field sources for high-field ESR/DNP measurements and low-frequency imaging, with a significantly increased active measurement volume compared to conventional coils.

According to one development of the invention, provision can be made for the inductive elements to be formed plate-shaped from a metal material (“Slab Metal Inductor”) or from a coil wire (“Single Turn Spiral Inductor”).

The above variants are to be understood only as examples and not as limiting. The inductive elements can in principle be realized in any way.

In one development of the invention, provision can in particular be made for the inductive elements to each be single-piece, monolithic components. For example, they can be respective contiguous, metalized sections in an integrated circuit, such as, e.g., tracks.

If necessary, however, the inductive elements can each also be formed in a plurality of parts (less preferred).

In one development of the invention, provision can be made for the inductive elements to be elongate components, in particular with a rectilinear profile.

Provision can be made for the longitudinal extent of the inductive elements in each case to preferably not exceed 20 millimeters (however, applications with larger longitudinal extents are of course also not excluded), preferably not exceed 10 millimeters, more preferably not exceed 5 millimeters, still more preferably not exceed 2 millimeters. However, one preferred application of the invention can relate to yet significantly smaller dimensions, wherein the longitudinal extent of the inductive elements does not exceed 1000 micrometers, preferably does not exceed 500 micrometers, more preferably does not exceed 200 micrometers, still more preferably does not exceed 100 micrometers. In particular, the individual inductive elements can be formed sufficiently small with regard to the wavelengths used in order to avoid parasitic radiation or at least reduce it sufficiently depending on the particular application.

In one advantageous development of the invention, provision can be made for the inductive segments to be connected to each other in a series arrangement, preferably in an at least substantially annular, self-contained arrangement.

In this case, two to 100 (or more) inductive segments can be provided, in particular up to 20 inductive segments, preferably four to eight inductive segments, for example exactly four inductive segments.

In particular, an even number of inductive segments can be provided.

In one advantageous development of the invention, provision can be made for the inductive elements to be electrically connected directly to the corresponding connection circuits or for the inductive elements to make direct electrical contact with corresponding terminals of the corresponding connection circuits.

However, an indirect electrical connection between the inductive elements and the connection circuits via further components or structures can also be provided if necessary.

In particular, provision can be made for the connection circuits to each have a first connection interface which is electrically connected or connectable to the inductive element of the same inductive segment and/or to each have a second connection interface which is electrically connected or connectable to an inductive element of an adjacent inductive segment.

According to one development of the invention, provision can be made for the connection circuits to each have a capacitive component, preferably a controllable capacitive component, in particular a varactor diode (“varactor”).

The capacitive component can preferably be arranged in the combination of the inductive segments in each case between two directly adjacent inductive elements. The capacitive component can thus be joined, for example, between the connection interfaces of the connection circuit.

In one advantageous development of the invention, provision can be made for the connection circuits to each have two cross-coupled transistors, preferably MOSFETs, bipolar transistors or GaN-based transistors.

The circuit arrangement of a single LC VCO can be designed, for example, such that a differential varactor diode and a differential inductor together form an LC oscillating circuit.

The two cross-coupled transistors can ensure stable oscillation in the differential output (i.e. the output voltage) through negative resistance and non-linearity, between two nodes. The tuning properties can be ensured by the differential varactor diode.

A time-dependent variation in the oscillation amplitude is implemented, e.g., by manipulating the power supply of the LC VCO. This simple design of an LC VCO ensures low power consumption, a small space requirement and also operates even at low (as far as cryogenic) temperatures.

Overall, within the scope of the present invention, a higher power consumption can be exchanged for a larger measuring volume with greatly reduced undesirable electric fields.

The proposed technique can be extended to produce homogeneous B₁ fields (in this context, B₁ fields are the microwave magnetic fields which resonate with the spin assembly) in three dimensions by combining two large-coil VCOs in a Helmholtz configuration or a plurality of large-coil VCOs to form a cylinder coil. If the individual coils are monolithic, they can be made possible, e.g., by drilling a hole through each large-coil VCO.

According to one development of the invention, provision can in particular be made for some or preferably all the inductive elements to be electrically connected to a common (central) star point, preferably arranged in a symmetrical arrangement around the common star point. The star point can thus then preferably form the center point of the arrangement. The electrical connection can in particular be established via respective high-resistance cable sections.

In this context, a “high-resistance cable section” can be understood to mean in particular a cable section the electrical resistance of which is greater than an electrical resistance of the inductive elements, preferably much greater, for example greater by one, two, three, four, five or yet more orders of magnitude.

In one advantageous development, provision can in particular be made for the common star point to be connected to an electrical reference potential, preferably to a ground potential.

Preferably, the connection circuits are designed as voltage-controlled oscillators. In one development of the invention, provision can, however, also be made for the connection circuits to each be designed as a driver circuit or another circuit which appears suitable.

The proposed arrangement of LC oscillators can be implemented in integrated circuit technology, i.e. completely with active and/or passive elements. The number of discrete components is thus reduced and, where appropriate, no further external components are necessary. This enables the realization of cost-effective, low-power and possibly transportable devices. The symmetrical design and high reproducibility of the individual circuit elements, such as is possible, e.g., in MEMS technology, is advantageous for the apparatus according to the invention. Interference signals can thus be reduced (especially in amplitude detection).

According to one development of the invention, provision can be made for the inductive element and the connection circuit of a common inductive segment to be formed in a common integrated circuit.

Preferably all the inductive segments of the inductive assembly are formed in a common integrated circuit.

However, provision can also be made for individual components or all the components to be formed not on an integrated circuit but rather, for example, as discrete electrical components, for example on an electrical circuit board.

The invention also relates to an oscillator arrangement, in particular for use in an apparatus for generating and/or detecting a magnetization of a sample, having at least one inductive assembly according to the above and below embodiments.

Preferably, the entire oscillator arrangement, in particular all the inductive assemblies of the oscillator arrangement, is formed in a common integrated circuit.

In one advantageous development of the invention, provision can be made for a plurality of the inductive assemblies to be connected to each other in a frequency-synchronized manner, preferably at least two inductive assemblies, more preferably at least four inductive assemblies, still more preferably at least eight inductive assemblies, still more preferably at least 16 inductive assemblies, for example at least 32 inductive assemblies or yet more inductive assemblies.

Here, frequency synchronization (frequency locking) can be understood to mean that the inductive assemblies have the same free oscillation frequency enforced by circuitry means.

In an advantageous manner, comparatively large inductors, i.e. inductors the circumference of which makes up a significant fraction of the wavelength, can thus be used as “tank inductors” in arrays of injection-locked VCO-based ESR detectors in order to increase the measurement volume in the direction perpendicular to the chip surface compared to conventional loop inductors.

In one embodiment, the frequency synchronization of the inductive assemblies can be realized by an interconnection as a coupling network. “Interconnected by a coupling network” can mean that the oscillation signal of an oscillator is fed into one or more other oscillators of the array by passive or else also active circuit elements. The effect of this is that the output signals of all the oscillators oscillate at the same frequency. In this case, the phase of the oscillation signals depends on the coupling network. This has the advantage that the oscillators are thus synchronized in their frequency and, by suitable selection of the coupling network, it is also possible to set a possibly desired defined phase shift between the oscillation signals of the oscillators. Depending on the type of the coupling network, the phase noise thus decreases compared to the phase noise of a single oscillator. Passive coupling networks consume less power than active networks.

In another embodiment, the frequency synchronization of the inductive assemblies can be realized by a network interconnection, wherein each LC oscillator has an additional input and an output voltage, at least one further LC oscillator, is fed into the additional input, wherein the LC oscillators are interconnected at least each on two sides. The effect of this is likewise that the output signals of all the oscillators oscillate at the same frequency. The phase likewise depends on the coupling network. Here too, this has the advantage that the oscillators are thus synchronized in their frequency and, by suitable selection of the network interconnection, it is also possible to set a possibly desired defined phase shift between the oscillation signals of the oscillators.

In one development of the invention, provision can be made for a plurality of the inductive assemblies to be arranged in a row and/or column arrangement, in particular in an array, wherein preferably at least two columns and/or at least two rows are provided. The oscillator arrangement is therefore sometimes also referred to as a “VCO array” below.

The spatial design of the arrangement of the inductive assemblies is implemented, in the case of a number of more than two inductive assemblies, as a planar composite system of individual inductive assemblies, preferably in rows and columns (also referred to as an “array”). It is thus possible to realize any arrangement of the inductive assemblies with respect to each other. The special case of a single row or chain is included here. In this case, the characterization as “planar” also encompasses arbitrarily curved surfaces with and without edges (e.g. cylinder surface, cone surface, sphere) in addition to a flat design.

The invention also relates to an apparatus for generating and/or detecting a magnetization of a sample, having an oscillator arrangement according to the above and below embodiments and a sample location for the sample.

The sample location can be a location in the apparatus at which the sample is arranged (optionally the sample can be fastened or fixed to the sample location) and at which both the magnetic field (B₀) and, where appropriate, the additional (e.g. transient) magnetic field (B₁) are present.

Means for fastening and storing the sample can be provided.

The design in which the transmitter and receiver are both implemented by a common arrangement is in particular advantageous since it allows a particularly simplified, cost- and space-saving construction.

In one development, provision can be made for the apparatus to have a device for providing a magnetic field, in particular for providing a static (or quasi-static) magnetic field, in a predetermined direction and strength at the sample location, wherein the oscillator arrangement is able to be used to provide an additional magnetic field at the sample location and/or to detect the magnetization of the sample at the sample location.

The device for generating said magnetic field of predetermined direction in the proposed apparatus is able to be realized, for example, by superconducting magnets or electromagnets of any design or permanent magnets.

The generated magnetic field is preferably static and corresponds to the magnetic field B₀ which is used to magnetize a sample suitable for magnetization and was already mentioned previously. In this case, the magnetic field can be of any strength so long as the frequency of the exciting B₁ magnetic field is selected in accordance with the resonance conditions.

In one development of the invention, provision can moreover be made for the apparatus to have a control device for controlling the oscillator arrangement, which control device is set up and connected to the oscillator arrangement such that the oscillator arrangement is used to generate a magnetic field which is capable of deflecting a magnetization of the sample at the sample location from a position of equilibrium.

The control device can be designed as a microprocessor. Instead of a microprocessor, any other device for implementing the control device can also be provided, for example one or more arrangements of discrete electrical components on a printed circuit board, a programmable logic controller (PLC), an application-specific integrated circuit (ASIC) or another programmable circuit, for example also a field-programmable gate array (FPGA), a programmable logic array (PLA) and/or a commercially available computer.

In one advantageous development of the invention, provision can be made for the sample location to be in the near field of the oscillator arrangement.

The near field can be understood here for the apparatus as the field of the LC oscillator in which, in the case of magnetically linear sample materials, because of J>>∂D/∂t the rotation of the B₁ field and also because of div B=0 the entire B₁ field is determined largely by the current density J in the inductive element. In contrast, because of J<<∂D/∂t wave propagation occurs in the far field. For the near field, it therefore applies that the B₁ field can be generated largely independently of the E₁ field since there is still no wave in the region of the near field. Due to this fact, it is possible to optimize the E₁ field much more freely or to keep said field low. Low E₁ fields minimize electrical losses in the sample as well as the loss caused by the heating of the sample, this being one possible advantage of the apparatus.

In one development, provision can be made for the apparatus to have an evaluation circuit for processing an output voltage of the oscillator arrangement, wherein the evaluation circuit preferably has means for demodulation, analog-to-digital converters and/or means for digital data processing.

The changes in the oscillation frequency of the arrangement of LC oscillators can be detected by demodulation downstream of the arrangement of LC oscillators. The demodulation can be done by a frequency demodulator. The analog signals are converted into digital signals by appropriate means, depending on the selected converters or demodulators, before or after the conversion or demodulation.

Changes in the oscillation amplitude can be detected by means downstream of the arrangement of LC oscillators. The amplitude of the individual LC oscillators in the arrangement is not synchronized by the coupling. A signal corresponding to the magnetization of the sample in the sensitive volume of this LC oscillator is therefore able to be tapped at each individual LC oscillator, respectively. Signals which allow local resolution are thus additionally obtainable. In this case, it should be noted that the amplitudes of the LC oscillators may be subjected to coupling within the LC oscillator, for which the signals may have to be corrected. The amplitude-modulated signal can be tapped by simple means at the individual LC oscillators. For this purpose, each LC oscillator only needs one amplifier for the signal (in continuous wave experiments usually in the kHz range) which, by the intrinsic demodulation, is directly available in the baseband when using a power source for supplying the LC oscillator, and is tapped at nodes in the LC oscillators. In this case, the signal does not have to be downmixed from the Larmor frequency. In addition to optimizing the complexity of the circuit, this also optimizes the power consumption.

In one development of the invention, provision can be made for the evaluation circuit to be set up to determine the magnetization of the sample and the spin concentration of individual spectral components that is to be ascertained therefrom.

According to one development of the invention, provision can moreover be made for the individual inductive elements of the inductive assemblies to have a longitudinal extent which does not exceed the wavelength of the operating frequency of the oscillator arrangement, preferably does not exceed half the wavelength of the operating frequency, particularly preferably does not exceed a quarter of the wavelength of the operating frequency, more preferably does not exceed a fifth of the wavelength of the operating frequency, for example does not exceed a tenth of the operating frequency.

At this point, it should be noted that the expression “connected” or “connection” used herein can describe a direct electrical connection of the mentioned components but also an indirect electrical connection of the mentioned components (that is to say, e.g., via further electrical cables or electronic components such as resistors, inductors and/or capacitors, etc.). Conversely, the expression “joined” or “in contact with” usually indicates a direct connection of the mentioned components.

The invention also relates to a method for generating and/or detecting a magnetization of a sample at a sample location, in particular for electron spin resonance spectroscopy or nuclear magnetic resonance spectroscopy, having at least the following step:
providing at least one inductive assembly which has a plurality of interconnected inductive segments, wherein each of the inductive segments has an inductive element and a connection circuit, which is electrically connected to the inductive element, for electrically connecting to an adjacent inductive segment.

Optionally, the following further method steps can, inter alia, also be provided:
providing a magnetic field, in particular a static magnetic field, in a predetermined direction and strength at the sample location;
operating the at least one inductive assembly to provide an additional magnetic field at the sample location, preferably a transient magnetic field, and/or to detect the magnetization of the sample at the sample location.

At this point, it should be stressed that method steps do not necessarily have to be carried out in the order in which they are first described or mentioned in the description or in the claims. For example, individual method steps or groups of method steps can therefore be interchangeable if this is not technically excluded. Method steps can also be combined with each other, divided into separate intermediate steps or supplemented with intermediate steps. The method is also not necessarily conclusively described with the method steps described below and can be supplemented with further method steps which are also not mentioned.

In one advantageous development of the invention, provision can be made for a plurality of the inductive assemblies to be operated in a frequency-synchronized manner with each other, preferably within a common oscillator arrangement.

In summary, a method for the synthesis of electrically large coils for improved 3D detection volumes in spin detection experiments such as ESR, NMR or FMR (ferromagnetic resonance) is proposed.

A plurality of oscillator cores can advantageously be combined to increase the sensitive volume for electron spin resonance detection.

In the case of the VCO-based detection, the proposed method preferably combines a plurality of VCOs to form a composite VCO with an electrically large coil. However, the method can also be applied in conventional transmit-receive spin detection setups.

The proposed method eliminates or inhibits the radiation effect associated with a large coil (preferably at least to a level that is negligible in practice or for the respectively intended application), which is highly undesirable, in particular in the case of liquid samples, and at the same time enables widely tunable VCO detectors with low phase noise.

The invention also relates to a computer program comprising control commands which, when the program is executed by a control device, cause the latter to perform the method according to the above and below specifications (or other work steps in the context of the overall concept according to the invention).

Features which have been described in connection with one of the subjects of the invention, namely given by the inductive assembly, the oscillator arrangement, the apparatus, the method and the computer program, can also be advantageously applied to the other subjects of the invention. Likewise, advantages specified in connection with one of the subjects of the invention can also be understood in relation to the other subjects of the invention.

In addition, it should be noted that expressions such as “comprising”, “having” or “with” do not exclude any other features or steps. Furthermore, expressions such as “a” or “the” that refer in the singular to steps or features do not exclude a plurality of features or steps—and vice versa.

Note that terms such as “first” or “second” etc. are used predominantly for the sake of distinguishability between respective apparatus or method features, and are not imperatively intended to indicate that features are mutually dependent or relate to one another.

Furthermore, it is stressed that the values and parameters described in the present case also encompass deviations or fluctuations of ±10% or less, preferably ±5% or less, more preferably ±1% or less, and very particularly preferably ±0.1% or less, of the respectively stated value or parameter, if these deviations are not ruled out in practice in the implementation of the invention. The specification of ranges by way of start and end values also encompasses all those values and fractions encompassed by the respectively stated range, in particular the start and end values and a respective mean value.

Moreover, it should also be stressed that the figures in each case show preferred exemplary embodiments in which individual features of the present invention are illustrated in combination with each other. However, features of one exemplary embodiment are also able to be implemented separately from the other features of the same exemplary embodiment and may accordingly be readily combined by a person skilled in the art to form further useful combinations and sub-combinations with features of other exemplary embodiments.

### BRIEF DESCRIPTION OF THE DRAWINGS

The invention is to be explained in more detail on the basis of the further figures mentioned below. The further figures show in each case schematically:

FIG. 1 An inductive assembly according to the invention for use in an oscillator arrangement, having a plurality of interconnected inductive segments;

FIG. 2 An inductive assembly according to the invention with further details;

FIG. 3 An exemplary chip-integrated realization of an inductive assembly according to the invention;

FIG. 4 An exemplary circuit arrangement of an inductive assembly according to the invention;

FIG. 5 An apparatus according to the invention for generating and/or detecting a magnetization of a sample at a sample location, having an oscillator arrangement which has a plurality of inductive assemblies in a row and column arrangement;

FIG. 6 A circuit diagram of an apparatus according to the invention;

FIG. 7 Measured electrical characteristics of an apparatus according to the invention;

FIG. 8 A further schematic circuit diagram of an apparatus according to the invention with further details;

FIG. 9 Exemplary measurement data of an ESR measurement; and

FIG. 10 A schematic circuit illustration of an apparatus for generating and detecting magnetic resonance.

### DESCRIPTION OF THE PREFERRED EMBODIMENTS

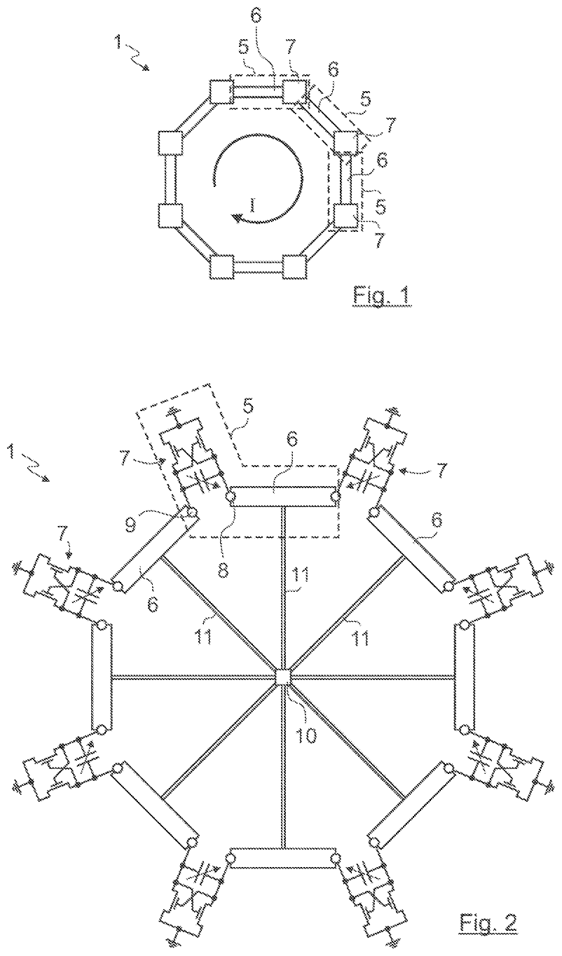

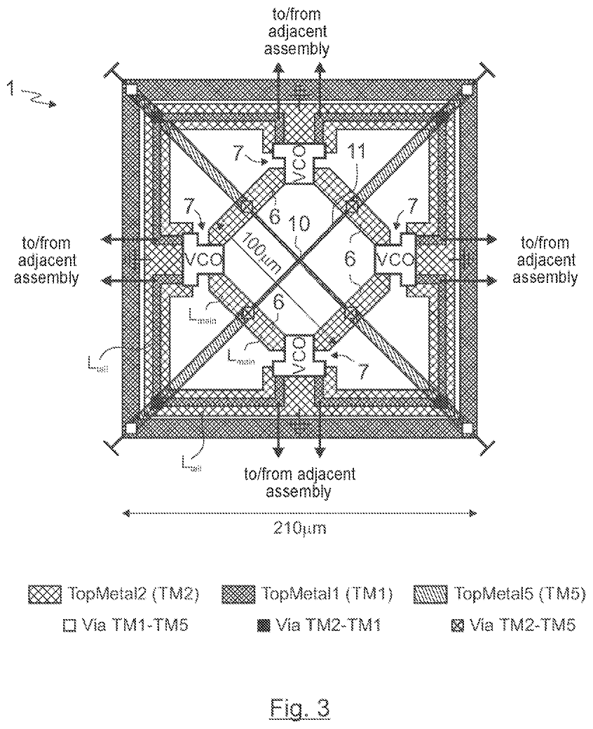

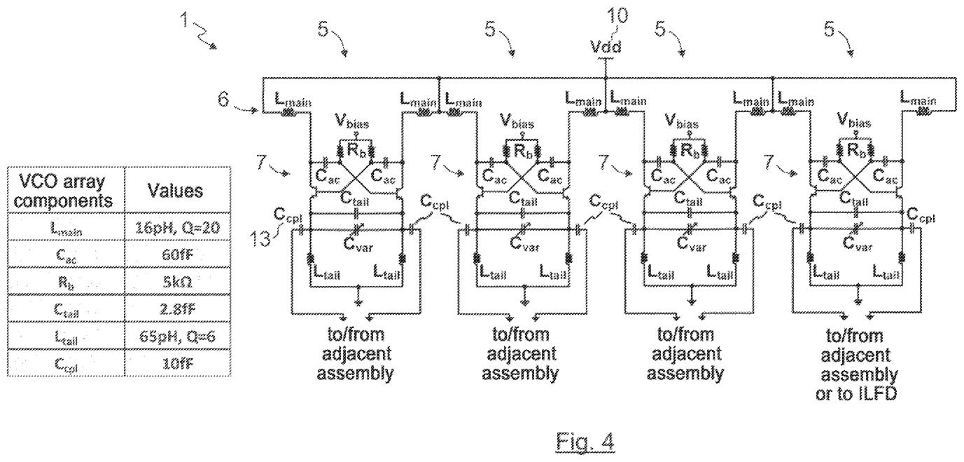

FIG. 1 shows an inductive assembly 1 in a greatly schematic illustration according to an exemplary embodiment of the present invention. FIG. 2 illustrates some further details and optional developments of the inductive assembly 1 by way of example. Exemplary implementations are shown in FIGS. 3 and 4.

The proposed inductive assembly 1 is suitable in particular for use in an oscillator arrangement 2 (cf., e.g., FIG. 5) for generating and/or detecting a magnetization of a sample 3 at a sample location 4.

The inductive assembly 1 has a plurality of interconnected inductive segments 5. Each of these inductive segments 5 comprises an inductive element 6 and a connection circuit 7, which is electrically connected to the inductive element 6, for electrically connecting to an adjacent inductive segment 5. The inductive segments 5 are connected to each other in a series arrangement and form an annular, self-contained arrangement in the exemplary embodiments.

FIGS. 1 and 2 illustrate the proposed concept using an exemplary split coil with eight coil segments or inductive elements 6 and eight electronic blocks/driver circuits or connection circuits 7. However, the illustration with exactly eight inductive segments 5 is only to be understood as an example. In principle, two to 20 inductive segments 5 can be provided, preferably four to eight inductive segments 5, for example exactly four inductive segments 5 (cf. also the implementations in FIGS. 3 and 4). Preferably, an even number of inductive segments 5 is provided.

As illustrated in the figures, a functionally comparatively large induction coil can thus be divided into a plurality of inductive (coil) segments 6 which are then electrically connected to each other by said connection circuits 7, e.g. driver circuits. The connection circuits 7 can (preferably at least approximately) ensure a phase relationship between the currents in the individual inductive elements 6 which corresponds to the current distribution in a low-frequency loop coil. With corresponding phase synchronization of the individual inductive elements 6 or inductive segments 5, a continuous alternating current I can thus flow (indicated in FIG. 1 by an arrow in the center of the inductive assembly 1), which mimics the response of the low-frequency alternating current in a simple loop coil.

In principle, an N-fold segmentation allows an N-fold increase in the outer circumference of the coil for a given radiation loss.

The inductive elements 6 can be electrically connected in particular directly to the corresponding connection circuits 7 or make direct electrical contact with corresponding terminals of the connection circuits 7. The connection circuits 7 can in particular each have a first connection interface 8 which is electrically connected to the inductive element 6 of the same inductive segment 5, and each have a second connection interface 9 which is electrically connected to an inductive element 6 of an adjacent inductive segment 5 (cf. in particular FIG. 2).

Provision can optionally be made to electrically and symmetrically connect all the inductive elements 6 to a common star point 10, as indicated by way of example in FIG. 2 and FIG. 3. This can preferably be done via respective high-resistance cable sections 11. The common star point 10 can be connected to an electrical reference potential Vdd, preferably to a ground potential. As a result, correct phase synchronization between the VCO cores can be ensured and a possible DC latch and other parasitic oscillation modes can be avoided. The high-resistance cable sections 11 can be realized by thin conductor tracks for bridging the central points of the inductive elements 6 connected to Vdd.

Optionally, auxiliary circuits (e.g. diodes) can also be used instead of the high-resistance cable sections 11 to suppress the undesired parasitic oscillation modes and keep the middle region of the large composite coil free at the same time, inter alia to allow the drilling of holes.

In order to connect the adjacent inductive elements 6 to each other in each case, the connection circuits 7 can in particular be VCO cores. The VCO cores can in particular each have a varactor diode Cᵥₐᵣ and two cross-coupled transistors (in particular MOSFETs, bipolar transistors or GaN-based transistors), as indicated in FIGS. 2 and 4, for example.

Controllable switches can be provided in order to switch each individual VCO core or each connection circuit 7 on and off as required, so that the overall inductance of the coil can be flexibly adjusted. In this way, a highly configurable, composite voltage-controlled oscillator having a very wide tuning range for ESR measurement in different frequency bands can be provided. According to the previously known prior art, the only way to achieve this is to use a plurality of ESR assemblies for different frequency bands in each case, this causing very high implementation costs.

As an alternative to the VCO case illustrated by way of example in FIG. 2, the connection circuits 7 can also be implemented as driver circuits or power sources, this making it possible to excite large volumes with a homogeneous B₁ field for conventional ESR experiments on a transmit/receive basis. In order to detect the ESR signal, the electromotive forces (EMFs) of each inductive segment 5 induced in each case can be detected and combined with each other.

The connection circuits 7 can be realized as cross-coupled VCO cores, this possibly leading, e.g., to an implementation according to FIG. 3. FIG. 3 shows an exemplary layout of a 263 GHz segment coil VCO cell (210 μm×210 μm) with four inductive segments, with VCO cores as connection circuits 7.

The inductive element 6 and the connection circuit 7 of a common inductive segment 5 can thus preferably be formed in a common integrated circuit (preferably all the inductive segments 5 of the inductive assembly 1 are formed in a common integrated circuit).

The inductive elements 6 can be formed plate-shaped from a metal material or from a coil wire. The inductive elements 6 are usually designed as elongate components and have in particular a rectilinear profile, wherein the longitudinal extent of the inductive elements 6 in each case preferably does not exceed 1000 micrometers, more preferably does not exceed 500 micrometers, still more preferably does not exceed 200 micrometers, very particularly preferably does not exceed 100 micrometers. At this point, it should be stressed once again that larger dimensions can also be used, wherein the longitudinal extent of the inductive elements 6 then, for example, does not exceed 20 millimeters, preferably does not exceed 10 millimeters, more preferably does not exceed 5 millimeters, still more preferably does not exceed 2 millimeters.

FIG. 3 shows only one advantageous example implementation, including exemplary connection interfaces to the adjacent inductive assemblies 1. In FIG. 3, the segmented coil forms the central square having a side length of 100 μm. Four VCO cores connect the individual inductive elements 6.

Thanks to the thus significantly increased diameter of the overall coil, the alternating current I generates the desired B₁ field in a much larger volume than in a conventional, non-segmented loop coil, while the radiation losses nevertheless remain low.

It has been shown that in the proposed segmented VCO, the oscillating VCO voltage is accessible at a plurality of outputs, this allowing the implementation of 2D “injection-locked” VCO arrays (cf. FIG. 3). In contrast, chip-integrated “injection-locked” ESR detectors of the prior art can only be coupled to the two nearest VCO neighbors, this leading to a largely linear injection scheme.

FIG. 4 shows an exemplary circuit model (e.g. for the implementation shown in FIG. 3) with exemplary size specifications for the individual electronic components of the VCO cell.

In order to provide a sufficient negative differential conductance through the cross-coupled pairs at the desired frequency (e.g. 263 GHz), use can be made of a capacitive degeneration circuit which, in combination with base-point inductors or tail inductors (Lₜₐᵢₗ) and “tail capacitors” (Cₜₐᵢₗ) arranged in parallel with the MOS varactors Cᵥₐᵣ, can act as an open element.

The base-point inductors Lₜₐᵢₗ can be realized, for example, as transmission lines or slab inductors (cf. FIG. 3).

An exemplary oscillator arrangement 2, in particular for use in an apparatus 12 for generating and/or detecting a magnetization of a sample, is illustrated in FIG. 5. The oscillator arrangement 2 has a plurality of inductive assemblies 1 according to the invention and a suitable sample location 4 for the sample 3.

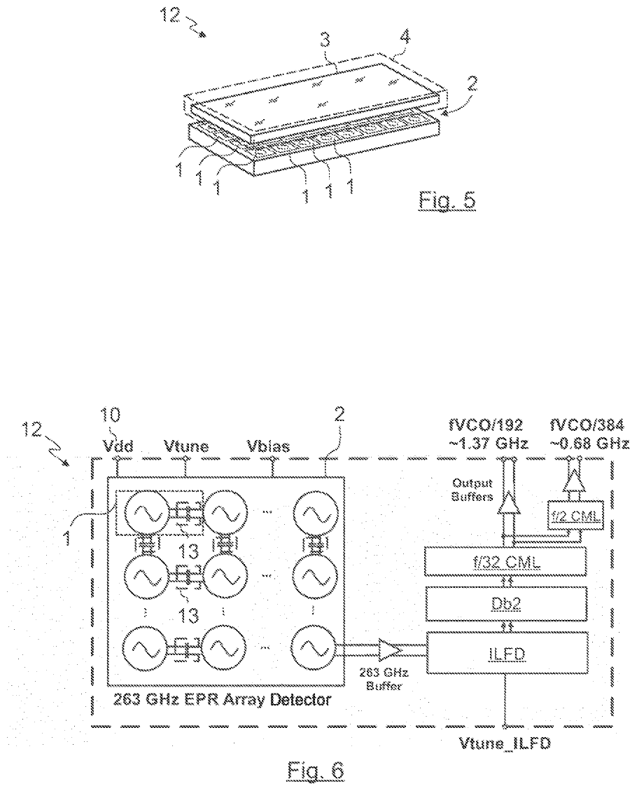

A possible apparatus 12 according to the invention for generating and/or detecting a magnetization of the sample 3, having a corresponding oscillator arrangement 2, is also illustrated with reference to the circuit diagram of FIG. 6.

The overall architecture of the VCO array chip shown in FIGS. 5 and 6 consists, by way of example, of 8×4 segmented VCOs or inductive assemblies 1, each of which is injection locked with the four adjacent inductive assemblies 1 via coupling capacitors 13 (e.g. 10 fF coupling capacitors).

The specific number of inductive assemblies 1 connected to each other in a frequency-synchronized manner does not necessarily matter in the context of the invention—but preferably a plurality of inductive assemblies 1 are arranged in a row and column arrangement (“array”), as indicated in FIG. 5 and FIG. 6, wherein preferably at least two columns and/or at least two rows are provided.

The common frequency of the oscillator arrangement 2 can be taken from one of the VCOs, buffered and further processed by a “divide-by-3 injection-locked frequency divider (ILFD)”. The input-related tuning range of the ILFD in the free-running state can be designed to be larger than that of the VCO array (e.g. 1 to 5 times larger, in particular 3 times larger) in order to ensure an overlap of the two ranges under all so-called PVT (“Process, Voltage and Temperature”) conditions.

The tuning voltage of the ILFD can be generated on the chip or outside the chip (e.g. to provide an additional degree of freedom for the common tuning of the ILFD and of the VCO array or of the oscillator arrangement 2). The output frequency of the ILFD can be fed into a regenerative divide-by-2 circuit (Db2) the output of which feeds a chain of CML dividers.

In the exemplary implementation, the oscillator arrangement 2 has two frequency outputs with division factors of 192 and 384, this corresponding to output frequencies of 1.37 GHz and 685 MHz, respectively.

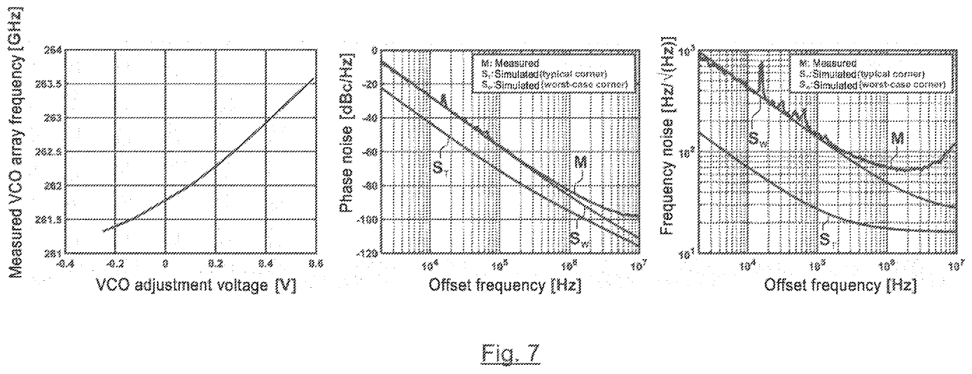

An exemplary chip was produced in 130 nm BiCMOS technology (fₘₐₓ=450 GHz), with a chip area of 4.2 mm² and a power consumption of 4.3 W. The possible tuning characteristics of the chip were measured (cf. graph on the left in FIG. 7); this is 2 GHz, which is sufficient for detecting most ESR spectra and covers the range of most DNP active substances. The phase and frequency noise were then measured. The corresponding results, relating to the VCO frequency, are likewise illustrated in FIG. 7 (the two graphs on the right). The measured results correlate well with the worst-case corner simulations.

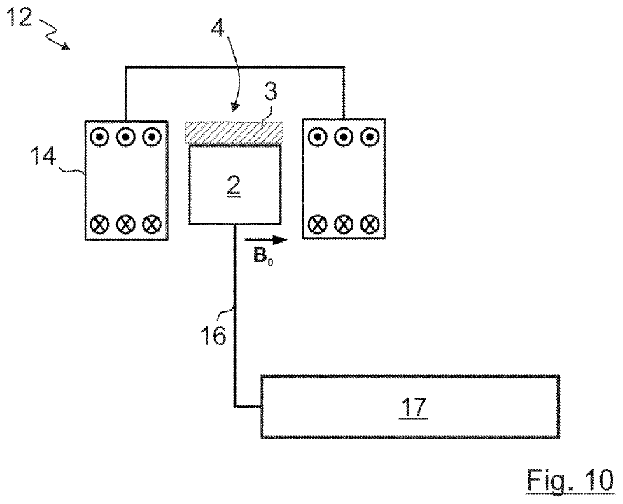

FIG. 8 illustrates an exemplary measurement setup for an apparatus 12 according to the invention. FIG. 10 additionally shows yet another schematic circuit arrangement of an apparatus 12 according to the invention. Since the basic principle of the measurement method is known, this is described only in a basic way below. For further details, reference is made to DE 10 2016 102 025 A1 or WO 2017/088852 A1, for example.

The apparatus 12 has a device 14 for providing a static magnetic field B₀ in a predetermined direction and strength at the sample location 4 (cf. in particular FIG. 10). A magnet, which can for example be a superconducting magnet (e.g. a 9.4 T magnet), an electromagnet of any design, a permanent magnet or an internal sample-intrinsic magnet (e.g. dipole fields), provides the static magnetic field B₀ at the sample location 4 at which a sample 3 is arranged. The magnetic field B₀ induces a magnetization in the sample 3 in accordance with the susceptibility of the sample 3.

The oscillator arrangement 2 is used to provide an additional magnetic field B₁ at the sample location 4. For this purpose, the sample location 4 is preferably in the near field of the oscillator arrangement 2. The oscillator arrangement 2 is controlled by a time-dependent waveform which serves as the control voltage which is used to determine the frequency of the oscillators in the oscillator arrangement 2, and a second time-dependent waveform which serves to manipulate the amplitude of the oscillation of the inductive assemblies 1 in the oscillator arrangement 2. The apparatus 12 can comprise a control device 15 for controlling the oscillator arrangement 2, which control device is set up to use the oscillator arrangement 2 to generate the magnetic field B₁ which is capable of deflecting the magnetization of the sample 3 at the sample location 4 from the position of equilibrium. The time-dependent waveforms can thus be provided by the control device 15 (e.g., a personal computer or another digital data processing device, cf. FIG. 8) and converted by digital-to-analog converters (not illustrated).

In order to also detect the magnetization of the sample 3 at the sample location 4, the output voltage 16 of the oscillator arrangement 2 is transferred to an evaluation circuit 17. The evaluation circuit 17 can preferably have means for demodulation, analog-to-digital converters and/or means for digital data processing. This evaluation circuit 17 can be set up to determine the magnetization of the sample 3 and the spin concentration of individual spectral components that is to be ascertained therefrom.

Information about the sample 3, which is contained in the frequency of the output voltage 16 of the arrangement of LC oscillators (for example resonance energies), can be prepared for further processing, e.g. in imaging or process management.

The magnetic field generated by the current-carrying inductive elements 6 inside the inductive assemblies 1 of the oscillator arrangement 2 is thus used to manipulate the magnetization of a sample 3. The resulting change in the sample magnetization in turn causes a change in the inductance of the inductive elements 6 or in the coils. This change in the individual coils or elements or inductive assemblies 1 then causes a change in the frequency of the arrangement of frequency-synchronized inductive assemblies 1 of the oscillator arrangement 2. The oscillator arrangement 2 therefore constitutes a transmitter with an extended active area. In addition, it also simultaneously constitutes a receiver for the changes in the magnetization caused in the sample 3, which magnetization is able to be determined by the oscillation frequency of the oscillator arrangement 2, which is a common oscillation frequency of the coupled, frequency-synchronized inductive assemblies 1.

Preferably, the individual inductive elements 6 of the inductive assemblies 1 have a longitudinal extent which does not exceed the wavelength of the operating frequency of the oscillator arrangement 2, preferably does not exceed half the wavelength of the operating frequency, particularly preferably does not exceed a quarter of the wavelength of the operating frequency, more preferably does not exceed a fifth of the wavelength of the operating frequency, for example does not exceed a tenth of the operating frequency.

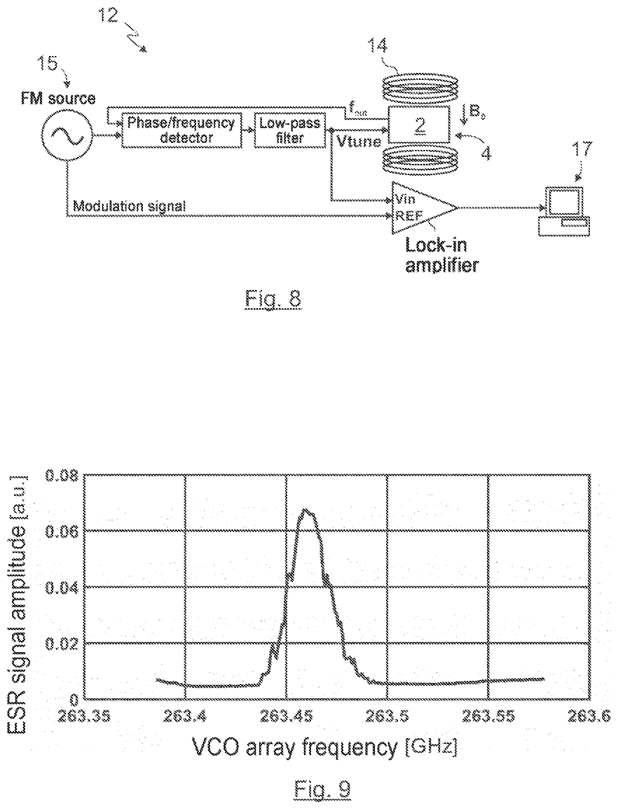

The resulting spectrum of an exemplary sample of BDPA, a customary ESR standard (i.e. a preliminary ESR spectrum, measured on a 720+/−30 nm film of α,γ-bisdiphenylene-β-phenylallyl (BDPA): benzene complex, diluted in polymethyl methacrylate (PMMA), 1.5% by weight), is illustrated in FIG. 9. The spectrum was recorded by the manufactured chip in a real measurement setup according to FIG. 8. For this purpose, the chip was embedded in a PLL on a PCB level. The ESR experiment was carried out with continuous wave frequency scanning (i.e. in the so-called continuous-wave mode) in a preclinical 9.4 T MRI scanner.

Overall, the proposed apparatus 12 based on the oscillator arrangement 2 according to the invention constitutes a promising alternative to the bulky and expensive conventional HFESR and high-frequency DNP devices owing to the increased detectable measurement volume at high frequencies on account of the large number of channels and the extended measurement range perpendicular to the chip surface by virtue of the segmented coil design.

Compared to a conventional gyrotron, the exemplary chip according to the invention generates similar B₁ strengths in the relevant range with a 109-fold reduction in size and a 1000-fold reduction in power consumption. In this case, the chip offers the frequency flexibility required by all modern DNP sequences and does not require any additional detection electronics. This can pave the way for the next generation of affordable yet powerful HFESR and DNP spectrometers.

For example, the invention can be used at field strengths in the range between 0.01 and 50 T, preferably in the range between 0.5 and 20 T, particularly preferably in the range between 5 T and 10 T, e.g. 9.4 T.

The invention can be used, e.g., at operating frequencies of between 1 and 500 GHz, preferably in the range between 10 and 400 GHz, particularly preferably in the range between 200 and 300 GHz, e.g. in the range between 261.3 and 263.6 GHz.

The invention can also advantageously be used for particularly low-frequency applications (in particular for imaging), e.g. at frequencies below 100 MHz, for example below 50 MHz, below 20 MHz, below 10 MHz or below 5 MHz. Even at such low frequencies, is advantageous to implement comparatively large coils in order to increase the concentration sensitivity in order to measure small animals using ESR imaging, for example.

The sensitive volume can be, e.g., 10 nl or more, e.g. 30 nl or more, e.g. 32 nl.

1. An oscillator arrangement for use in an apparatus for generating and/or detecting a magnetization of a sample, comprising a plurality of inductive assemblies, each inductive assembly of the plurality of inductive assemblies comprising a plurality of interconnected inductive segments,
wherein, in an inductive assembly of the plurality of inductive assemblies, each inductive segment of the plurality of inductive segments includes an inductive element and a connection circuit, which is electrically connected to the inductive element, for electrically connecting to an adjacent inductive segment,
wherein inductive assemblies of the plurality of the inductive assemblies are connected to each other in a frequency-synchronized manner,
wherein the inductive element and the connection circuit of a common inductive segment are formed in a common integrated circuit, and
wherein, in each inductive assembly of the plurality of inductive assemblies, the inductive segments are connected to each other in an at least substantially annular, self-contained series arrangement.

2. The oscillator arrangement claimed in claim 1,
wherein all the inductive segments of an inductive assembly, of the plurality of inductive assemblies, are formed in the common integrated circuit.

3. The oscillator arrangement as claimed in claim 1,
wherein the inductive elements of an inductive assembly, of the plurality of the inductive assemblies, are formed plate-shaped from at least one of a metal material (“Slab Metal Inductor”) and a coil wire (“Single Turn Spiral Inductor”).

4. The oscillator arrangement as claimed in claim 1,
wherein each inductive element of an inductive assembly, of the plurality of the inductive assemblies, is a single-piece, monolithic component.

5. The oscillator arrangement as claimed in claim 1,
wherein each inductive element of an inductive assembly, of the plurality of the inductive assemblies, is an elongate component, and wherein a longitudinal extent of each inductive element does not exceed 10 millimeters.

6. (canceled)

7. (canceled)

8. (canceled)

9. The oscillator arrangement as claimed in claim 1,
wherein each inductive elements of an inductive assembly of the plurality of the inductive assemblies, is either a) electrically connected directly to a corresponding connection circuits or b) makes a direct electrical contact with a corresponding terminal of the corresponding connection circuit.

10. The oscillator arrangement as claimed in claim 1,
wherein each connection circuit of an inductive assembly, of the plurality of inductive assemblies, includes a first connection interface which is electrically connected to the inductive element of the same inductive segment, and further includes a second connection interface which is electrically connected to the inductive element of an adjacent inductive segment.

11. The oscillator arrangement as claimed in claim 1,
wherein each connection circuit of an inductive assembly, of the plurality of inductive assemblies, is designed as at least one of (i) a driver circuit and (ii) a voltage-controlled oscillator (VCO).

12. The oscillator arrangement as claimed in claim 1,
wherein each connection circuits of an inductive assembly, of the plurality of inductive assemblies, includes a capacitive component.

13. (canceled)

14. The oscillator arrangement as claimed in claim 1,
wherein each connection circuit of an inductive assembly, of the plurality of inductive assemblies, includes two cross-coupled transistors.

15. The oscillator arrangement as claimed in claim 1,
wherein all the inductive elements of an inductive assembly, of the plurality of the inductive assemblies, are electrically connected to a common star point. 16. The oscillator arrangement as claimed in claim 15,
wherein the common star point is connected to an electrical reference potential (Vdd).

17. (canceled)

18. (canceled)

19. The oscillator arrangement as claimed in claim 1,
wherein the plurality of the inductive assemblies is arranged in a row and column arrangement (“array”).

20. An apparatus for generating and/or detecting a magnetization of a sample, comprising:
an oscillator arrangement comprising a plurality of inductive assemblies, each inductive assembly of the plurality of inductive assemblies comprising a plurality of interconnected inductive segments,
wherein, in an inductive assembly of the plurality of inductive assemblies, each inductive segment of the plurality of inductive segments includes an inductive element and a connection circuit, which is electrically connected to the inductive element, for electrically connecting to an adjacent inductive segment,
wherein inductive assemblies of the plurality of the inductive assemblies are connected to each other in a frequency-synchronized manner,
wherein the inductive element and the connection circuit of a common inductive segment are formed in a common integrated circuit, and
wherein, in each inductive assembly of the plurality of inductive assemblies, the inductive segments are connected to each other in an at least substantially annular, self-contained series arrangement; and
a sample location.

21. The apparatus as claimed in claim 20,
further comprising a device for providing a first magnetic field (B0), in a predetermined direction and of a predetermined strength at the sample location,
wherein the oscillator arrangement configured for at least one of (i) providing an additional magnetic field (B1) at the sample location, and (ii) detecting the magnetization of the sample at the sample location.

22. The apparatus as claimed in claim 20,
further comprising a control device for controlling the oscillator arrangement in such a way that the oscillator arrangement generates an additional magnetic field (B1) which is capable of deflecting a magnetization of the sample at the sample location from a position of equilibrium.

23. The apparatus as claimed in claim 20,
wherein the sample location is in a near field of the oscillator arrangement.

24. The apparatus as claimed in claim 20,
further comprising an evaluation circuit for processing an output voltage of the oscillator arrangement.

25. The apparatus as claimed in claim 20,
wherein the evaluation circuit is configured to determine a magnetization of the sample and a spin concentration of individual spectral components.

26. (canceled)

27. A method or generating and/or detecting a magnetization of a sample at a sample location, for electron spin resonance spectroscopy or nuclear magnetic resonance spectroscopy, comprising the steps of:
providing at least one inductive assembly having a plurality of interconnected inductive segments that are connected to each other in an at least substantially annular, self-contained series arrangement,
wherein each inductive segment, of the plurality of inductive segments, includes an inductive element and a connection circuit, which is electrically connected to the inductive element, for electrically connecting to an adjacent inductive segment, and wherein the inductive element and the connection circuit of each common inductive segment are formed in a common integrated circuit;
providing a magnetic field (B0) in a predetermined direction and of a predetermined strength at the sample location; and
operating the at least one inductive assembly to perform at least one of (i) provide an additional magnetic field (B1) at the sample location, and (ii) to detect a magnetization of the sample at the sample location.

28. (canceled)
